(19) United States
(12) Patent Application Publication
(10) Pub. No.: US 2023/0350385 A1
(43) Pub. Date: Nov. 2, 2023

(54) METHOD AND SYSTEM FOR ADJUSTING A DRYING PROCESS DESIGNATED FOR PRODUCING A COATING

(71) Applicant: BASF SE, Ludwigshafen am Rhein (DE)

(72) Inventors: Benjamin Schmidt-Hansberg, Ludwigshafen am Rhein (DE); Clemens Thomas Chan-Braun, Ludwigshafen am Rhein (DE); Marcel Schmitt, Ludwigshafen am Rhein (DE); Fatih Cetinel, Ludwigshafen am Rhein (DE); Felix Eberle, Ludwigshafen am Rhein (DE); Uwe Wolf, Ludwigshafen am Rhein (DE); Stephan Schaefer, Ludwigshafen am Rhein (DE)

(21) Appl. No.: 18/028,904

(22) PCT Filed: Sep. 29, 2021
(86) PCT No.: PCT/EP2021/076839

§ 371 Date: Mar. 28, 2023

(30) Foreign Application Priority Data
Sep. 29, 2020 (EP) 20198988.6

(51) Int. Cl. G05B 19/4155; B05D 3/02

(52) U.S. Cl. CPC G05B 19/4155; B05D 3/0254; G05B 2219/49051

(57) ABSTRACT

A computer-implemented method and system for adjusting at least one drying process designated for producing at least one coating on at least one substrate are provided herein. The at least one drying process is applied to at least one preparation deposited on the at least one substrate, wherein the at least one drying process comprises at least two consecutive drying stages after which the at least one coating is produced Further disclosed are a related method and system for continuously producing the at least one coating on the at least one substrate.

### FIELD OF THE INVENTION

The present invention refers to a computer-implemented method and a system for adjusting at least one drying process designated for producing at least one coating on at least one substrate as well as to a related method and system for continuously producing the at least one coating on the at least one substrate which involve the computer-implemented method and system. In particular, the present invention refers to adjusting at least one drying process which occurs during producing a battery electrode or a solar cell. However, further applications are feasible.

### PRIOR ART

A drying process which is designated for producing at least one coating on at least one substrate as well as methods and systems for continuously producing the at least one coating on the at least one substrate are well-known. Adjusting such a drying process which may occur during a production process for a particular product, such as a battery electrode or a photoactive layer for a solar cell, may, especially, be driven to, concurrently, improve a product quality at constant or increasing process efficiency.

As an example, S. Jaiser, Film Formation of Lithium-Ion Battery Electrodes during Drying, Dissertation, Karlsruher Institut für Technologie (KIT), 2017, pp. 227-228, describes a basic approach to a reduction of a drying time of lithium ion battery anodes while using a particular drying profile. With regard to an adhesion of graphite anodes, an existence of a characteristic stage which exhibits a distinct sensitivity to drying boundary conditions has been demonstrated. A low evaporation rate was adjusted during the characteristic stage to prevent a binder from depleting at film domains close to the substrate. In order to reduce a total drying time, a high evaporation rate was adjusted during initial and final drying stages. For this purpose, the drying evaporation rate was solely altered by a variation in aerodynamic gas flow conditions. A film temperature during drying as well as a solvent loading in a gas phase were considered as major drying parameters.

As a further example, Sanyal et al., Adv. Energy Mater. 2011, 1, 363-367, describe the relevance of drying conditions for the manufacturing of organic solar cells. Further, Schmidt-Hansberg et al., ACS Nano 2011, 5, 11, 8579-8590 showed, that there also exists a certain critical instance in the drying step which is responsible for structure formation and consequently solar cell performance.

US 2019/081317 A1 discloses a dual sided coating system and a method for coating substrates, such as substrates useful as battery electrodes.

WO 2014/129214 A1 discloses a simulation device for drying a coating and a device for drying a coating.

Further, Ternes et al., Adv. Energy Mater. 2019, 9, 1901581 reveal a correlation between drying process parameters, a solar cell layer structure and a solar cell performance for perovskite solar cells.

### Problem to be Solved

It is, therefore, an object of the present invention to provide a computer-implemented method and system for adjusting at least one drying process designated for producing at least one coating on at least one substrate as well as to a method and a system for producing the at least one coating on the at least one substrate, which may at least partially overcome the above-mentioned technical disadvantages and shortcomings of known.

In particular, it is an object of the present invention to provide a simple and easily available access to adjusting at least one drying process designated for producing at least one coating on at least one substrate. It is, especially, desirable that the adjusting of the drying process may be designed to improve a quality of a product whose manufacturing includes at least one drying process at constant or increasing efficiency of the drying process, in particular with regard to at least one of a throughput during production, a performance of the at least one coating, and an energy consumption during the drying process.

### Summary of the Invention

This problem is solved by the invention with the features of the independent patent claims. Advantageous developments of the invention, which can be implemented individually or in combination, are presented in the dependent claims and/or in the following specification and detailed embodiments.

In a first aspect of the present invention, a computer-implemented method for adjusting at least one drying process designated for producing at least one coating on at least one substrate is disclosed. Herein, the at least one drying process is applied to at least one preparation deposited on the at least one substrate, wherein the at least one drying process comprises at least two consecutive drying stages after which the at least one coating is produced. According to the present invention, the method comprises the following steps:
(i) receiving information about a layout of the at least two consecutive drying stages, about a composition of the preparation, and about the at least one substrate;
(ii) employing at least one model configured to generate at least one predictive value for at least one setting parameter for at least one associated dryer being used during at least one of the drying stages;
(iii) determining the at least one predictive value for the at least one setting for the at least one associated dryer being used during the at least one of the drying stages based on the at least one model and the information; and
(iv) providing at least one recommended procedure for adjusting the at least one drying process which comprises the at least one predictive value for the at least one setting parameter for the at least one associated dryer suitable for being used during the at least one of the drying stages.

In particular, the drying stage may be independent from the number or position of drying zones of the coating device.

The layout of the drying stage may in particular refer to the layout of a drying zone of the coating device.

As generally used, the term “computer-implemented method” relates to a particular kind of method which involves at least one programmable apparatus, in particular a computer, a server, a computer network, or a mobile communication device, wherein all steps of the method are implemented by using a computer program. The term “computer network” refers to any kind of infrastructure which comprises at least two computers and at least one communication interface, wherein at last one computer has access to at least one further computer via the at least one communication interface. Herein, the computer network can, preferably, be selected from at least one of an internet, an intranet or a local-area network. However, further kinds of computer networks may also be feasible. Further, the term “mobile communication device” refers to a particular type of programmable apparatus which is configured to be carried by a user and may, therefore, be moveable together with the user. Herein, the mobile communication device can, preferably, be selected from at least one of a smartphone, a tablet, or a personal digital assistant. However, further kinds of mobile communication devices may also be feasible.

As further generally used, the terms “computer program” and “software” relate to a series of computer-readable instructions configured to be provided to a programmable apparatus in order to perform at least one method step in consequence of at least one of the instructions. For this purpose, the computer program may comprise at least one algorithm configured to exert at least one particular operation by which the at least one method step is performed in a direct or an indirect fashion. The computer program can be selected from “software as a product”, which is configured to be transferred to at least one user, especially via payment and/or licensing, or from “software as a service”, which is configured to be centrally hosted and to be used by at least one user via at least one communication interface configured for network access, specifically on a subscription basis.

The computer-implemented method according to the present invention is designed for adjusting at least one drying process which is designated for producing at least one coating on at least one substrate, preferably in a coating device which is configured for this purpose. Herein, the at least one drying process is applied to at least one preparation which is deposited on the at least one substrate. As generally used, the term “preparation” refers to a substance which comprises at least two different components, i.e. at least one first component and at least one second component. Herein, the at least one first component may be or comprise a plurality of at least one solid component, wherein the at least one solid component may comprise a plurality of at least one of crystalline particles, amorphous particles, or dissolved molecules. Especially, an entirety of the solid components may also be denoted as “matrix”. Further, the at least one second component may be or comprise at least one fluidic component also be denominated by the term “solvent”, wherein the at least one solvent may be selected from at least one of a liquid, a gas, or a mixture thereof. In addition, the preparation may comprise at least one additional component, in particular at least one binder, wherein the term “binder” refers to a further substance designated to maintain the solid components within the matrix at least partially, preferably completely, together. However, further types of components may also be conceivable.

As generally used, the term “drying process” relates to an engineering procedure which is designated for reducing a content of the at least one second component, i.e. of the at least one solvent, which is comprised by the preparation to be dried, preferably until the content of the at least one solvent may be below a predefined threshold. In accordance with the present invention, the drying process is applied to at least one preparation to be dried which is deposited on at least one substrate. As a result of the drying process, the desired coating is produced on the at least one substrate. As further generally used, the term “substrate” refers to a mechanical support which is designated for receiving a portion of the preparation to be dried in the drying process and, subsequently, for maintaining the coating as the result of the drying process on the substrate. As further used herein, the term “depositing” refers to applying a portion of the preparation onto an adjacent surface of the substrate. The substrate may be selected from any material which is capable of receiving the portion of the preparation and of maintaining the coating as produced, wherein the substrate may, preferably, be inert, wherein the term “inert” relates to an observation that a contact of neither the preparation nor of the coating with the adjacent surface of the substrate may lead to any kind of degradation of the substrate.

As further indicated above, the at least one drying process comprises at least two consecutive drying stages after which the at least one coating is produced. As generally used, the term “drying stage” refers to a period of the drying process which is characterized by at least one value for at least one setting parameter for at least one associated dryer which is used during at least one of the drying stages. In particular, the at least one setting parameter for the at least one associated dryer may comprise at least one of an individual temperature profile and an individual heat transfer profile which may be applied during a corresponding drying stage. In other words, a particular drying stage is distinguished from an adjacent drying stage by selecting at least one value for the setting parameter for the at least one associated dryer in a fashion that it differs from the at least one value for the setting parameter for the at least one associated dryer in the adjacent drying stage. As used herein, the term “individual temperature profile” relates to a course of the temperature prevailing at the preparation during the corresponding drying stage while the term “individual heat transfer profile” refers to a course of the heat transfer applied to the preparation during the corresponding drying stage. Herein, the temperature may, specifically, refer to a temperature at an accessible surface of the at least one preparation as applied on the at least one substrate while the heat transfer may, especially, refer to a transfer of heat above the accessible surface of the at least one preparation. Herein, the at least one individual temperature profile may, preferably, be set by using at least one temperature control unit which is configured to control at least one of a heating unit or a cooling unit, while the at least one individual heat transfer profile may, preferably, be set by using at least one blowing unit. Herein, at last one of individual temperature profile or the individual heat transfer profile may, preferably, be set to a constant value during a particular drying stage.

The computer implemented method may further comprise the steps of providing the information about a layout of the at least two consecutive drying stages, about a composition of the preparation, and about the at least one substrate and receiving the at least one recommended procedure for adjusting the at least one drying process which comprises the at least one predictive value for the at least one setting parameter for the at least one associated suitable for being used during the at least one of the drying stages. Thus, the information may be remotely provided such as by or via an external server. Further, the at least one recommended procedure may be remotely received such as by or via an external server. With other words, both steps may be carried out at different or separate device.

In a particular embodiment of the present invention, the consecutive drying stages may comprise at least one initial drying stage and at least one critical drying stage which may follow the at least one initial drying stage. Herein, the at least one setting parameter for the at least one associated dryer may be adjusted during the at least one critical drying stage in a fashion to, generally, differ from the at least one setting parameter for the at least one associated dryer as adjusted during the at least one initial drying stage. In a further embodiment in which the drying process may comprise at least three consecutive drying stages, the at least three consecutive drying stages may further comprise at least one final drying stage which may follow the at least one critical drying stage. Herein, the at least one setting parameter for the at least one associated dryer during the at least one final drying stage may be adjusted in a fashion to, generally, to differ from the at least one setting parameter for the at least one associated dryer as adjusted during the at least one critical stage.

Not wishing to be bound by theory, the use of the different drying stages may be adapted to the composition of the at least one preparation. As already indicated above, the preparation, typically, comprises at least two different components, i.e. a matrix having a plurality of at least one solid component, wherein the at least one solid component may comprise a plurality of at least one of crystalline particles, amorphous particles or dissolved molecules, a solvent having at least one second component, wherein the at least one solvent may be selected from at least one of a liquid, a gas, or a mixture thereof, and, optionally, at least one binder designated to maintain the solid components within the matrix together. In order to form the coating during the at least one drying process, a combination of particle consolidation, binder migration and solvent evaporation occurs during the consecutive drying stages. In general, immediately after having applied the at least one preparation onto the at least one substrate, the at least one drying process, typically, commences with the initial drying stage which comprises a shrinkage of a volume of the at least one preparation on the at least one substrate, in particular, due to a combination of particle consolidation and solvent evaporation from the matrix. Thereafter, the critical stage, typically, commences when the shrinkage of the volume of the at least one preparation on the at least one substrate finishes and the solvent evaporation from pores between the consolidated particles commences. As experimentally demonstrated, it may, thus, be particularly preferred to apply a different drying profile during the critical drying stage to adequately support procedures which take place during the critical drying phase in order to obtain a high quality of the coating within as little time as possible. During the final drying stage, the value for the solvent volume fraction can, eventually, be reduced to almost zero, especially by applying a considerably high evaporation rate to reduce the drying time as far as possible.

In particular in a manufacturing of at least one of a positive electrode or a negative electrode for a battery, such as a lithium ion battery, the drying process may exhibit a specific mechanism. The coated preparation may, typically, comprise particles which can be dispersed in a binder solution, wherein the at least one binder can be selected from a dissolved polymer or a polymer dispersion. As a consequence of this particular preparation, a specific electrode formation mechanism during drying of the coating may occur. This mechanism exhibits at least two consecutive stages, in particular, three characteristic stages referring to the film composition space which is independent from the layout, in particular, number or position of drying zones of the coating and drying equipment. In an initial drying stage, the coated preparation on the substrate may be shrinking in the course of solvent evaporation, leading to a consolidation of the particles up to a formation of a porous network in which particles may have contact with each other, such that a shrinkage of the coating may be stagnating. In a subsequent drying stage, further solvent may be evaporating from the porous network. In the subsequent drying stage, the binder may be migrating to a surface with a rate which increases with the solvent evaporation rate as adjusted by dryer settings. In a final drying stage, the binder may not be sensitive to migration anymore, in particular due to a reduced solvent fraction and a, consequently, increased viscosity. For this specific mechanism, a particular drying process as used for drying at least one of a positive electrode or a negative electrode for a battery, such as a lithium ion battery, may, preferably, follow a specific three-stage drying process which differs from a typical drying process as used for other material systems, such for a drying of at least one photoactive layer in a coating of a solar cell, especially selected from an organic photovoltaic, a polymer solar cell or a perovskite-based solar cell, wherein the drying process may, however, also exhibit an impact on the final properties of the coating. In these mentioned photovoltaic related systems, the correlation between drying process and product performance underlies the mechanism of crystallization of salts, small molecules or polymers with decisive parameters such as crystal fraction, crystal size and orientation. This leads to different optimization criteria as well as fully different process parameters compared to battery electrodes. In battery electrodes the decisive mechanism is the formation of a binder and conductive additive gradient which governs the battery performance.

Providing the at least one recommended procedure for adjusting the at least on drying process based on drying stages that are independent from the number or position of drying zones of the coating and drying equipment allows adjusting according to the physical and chemical requirements. This may allow a more flexible adjustment of the production and therefore a better use of production capabilities, in particular while maintaining quality. The dependency from an existing physical coating device layout is reduced. Particularly, it is explicitly stated that a drying stage may be split, divided, partitioned or the like onto more than one drying zone such as two drying zone. With other words, one portion of a drying stage may be carried out or take place in a drying zone and another portion of the drying stage may be carried out or take place in another drying zone such as a consecutive drying zone.

In general, the drying process may be selected from a batch drying process or a continuous drying process, wherein the continuous drying process may, particularly, be preferred. As generally used, the term “the batch drying process” refers to a particular drying process in which each drying stage is performed consecutively on the same preparation, preferably, without moving the substrate, especially, within a single drying zone in which the at least two consecutive drying stages are, consecutively, performed. In contrast hereto, the term “continuous drying process” relates to a particular drying process which may, especially, be performed in a coating device which comprises at least one tape which is transported in a continuous fashion with a tape speed, preferably with a constant tape speed, through at least two consecutive drying zones, wherein each drying zone may, in particular, be designated for performing one of the at least two consecutive drying stages. Herein, the at least one tape may be or comprise the at least one substrate, or, as an alternative, the at least one tape may carry the at least one substrate for transport. Herein, at last one of individual temperature profile or the individual heat transfer profile may, preferably, be set to a constant value within a particular drying zone.

As further used herein, the term “adjusting” or any grammatical variation thereof relates to a procedure which is designated for arranging at least one parameter of the drying process in an desired fashion. Preferably, the adjusting of the drying process may be performed in a fashion that at least one material parameter of the at least one coating on the at least one substrate which is obtained by performing the at least one drying process may be improved at constant or, preferably, increasing efficiency of the drying process. As used herein, the term “efficiency” refers to at least one of a throughput during the production, a performance of the at least one coating, and an energy consumption during the drying process. In this manner, the product which involves the at least one coating on the at least one substrate may exhibit a higher quality which can be obtained at the same or, preferably, at lower efforts and expenses.

According to step (i), information about a layout of the at least two consecutive drying stages, about a composition of the preparation, and about the at least one substrate is received. Herein, the information about the layout of the at least two consecutive drying stages may, especially, comprise the layout of the drying zone, more particular, details about each drying zone and the at least one associated dryer which is used in each drying zone during a drying stage. Preferably, this piece of information may comprise at least one of a length of each drying zone; a type of dryer, preferably selected from at least one of a convective dryer, a radiative dryer, specifically based on infrared, UV, micro-wave, or radio-wave, or a contact dryer; at least one setting of the dryer, especially with respect to at least one location on a top or a bottom of the dryer, specifically at least one temperature; a blower setting; a ratio between fresh and recirculated drying gas which determines the fraction of evaporated solvent in the drying gas; a heat transfer coefficient; a convective drying nozzle slit width; a convective drying nozzle to nozzle distance; a convective drying nozzle distance to the substrate; a radiation source power; a distance in-between radiation sources; a distance radiation source to the substrate, a spectral distribution of the radiation source. Further, the information about the composition of the preparation may, preferably, comprise at least one of a type and concentration of the solid material, of the solvent, of a possible additive, a thickness and a coating weight per area of the preparation, or a porosity of the resulting coating. Further, the information about the at least one substrate may, preferably, comprise at least one of a type of the substrate, such as a foil, a non-woven, a woven, a fabric, a paper, or a glass substrate; a composition, a porosity, a thickness, or a weight per area of the substrate material. However, at least one further piece of information may also be feasible. Regarding step (i) it has to be noted that the information about a layout of the at least two consecutive drying stages, about a composition of the preparation, and about the at least one substrate may particularly be provided by a user of a drying apparatus comprising the two drying stages such as an operator of an industrial plant. The information about a layout of the at least two consecutive drying stages, about a composition of the preparation, and about the at least one substrate may then be received by a third party such as a supplier for the preparation. The information may be exchanged via any wired or wireless manner such as via the internet or any other network.

For receiving the pieces of information according to step (ii), the programmable apparatus on which the computer-implemented method as disclosed herein is performed comprises at least one of an input function or a communication interface by any one of which the desired pieces of information are provided in form of data to the programmable apparatus for further processing. As generally used, the term “input function” refers to a unit as comprised by the programmable apparatus which is configured to receive the pieces of information by manually or automatically generating the pieces of information for being used by the programmable apparatus. In particular, the input function may comprise at least one of a keypad, or a virtual keypad as displayed on at least one monitor. However further kinds of input functions may also be conceivable.

As further generally used, the term “communication interface” relates to a transmission channel designated for a transmission of data from a further programmable apparatus to the programmable apparatus on which the computer-implemented method as disclosed herein is performed. In particular, the communication interface may be arranged as a unidirectional interface which is configured to forward at least one piece of information into a single direction, especially to the programmable apparatus. Alternatively, the communication interface may be arranged as a bidirectional communication interface which is configured to forward at least one piece of data into one of two directions, or vice versa. Herein, the bidirectional communication interface can be used for forwarding requests or messages to the further programmable apparatus, such as a request for providing data or an error message. For the purpose of data transmission, the communication interface may comprise a wire-bound element or a wireless element. By way of example, the wire-bound element may be selected from at least one of a metal wire, such as a copper wire or a gold wire; a computer bus system, such as a universal serial bus (USB); or an optical fiber, whereas the wireless element may comprise a wireless transmitter or a Bluetooth element. However, further kinds of communication interfaces may also be feasible.

According to step (ii), at least one model is employed, wherein the at least one model is configured to generate at least one predictive value for at least one setting parameter for at least one associated dryer being used during at least one of the drying stages. As used herein, the term “model” relates to at least one computer program which is configured to generate a simulation of the drying process, wherein the drying process comprises the at least two consecutive drying stages. In particular, to achieve appropriate results, the simulation may closely be based on the information about the layout of the at least two consecutive drying stages, about the composition of the preparation, and about the at least one substrate as received during step (i). As further used herein, the term “employing” refers to a process of providing and using the at least one model, particularly in a fashion as required by the present invention. In order to employ the model, information on the preparation need to be provided such as information on the components thereof such as active material, binder, additives, solvent and composition in %. Thus, a specific coating weight in g/m² may be defined as target setpoint, a tape speed in m/min, which relates to the throughput, and a ratio of circulating air in the drying zones may be determined.

The model may relate the information with drying stages for determining the at least one predictive value for the at least one setting parameter for the at least one associated dryer.

As further used herein, the term “predictive value” relates to at least one value which is determined by using the at least one model in a fashion that it can be used for the at least one setting parameter for the at least one associated dryer being used during the at least one of the drying stages. However, further predictive values may, additionally, be generated, in particular a predictive valued for a tape speed as described below in more detail.

In a particularly preferred embodiment, the at least one model may be generated by using at least one known value for the at least one setting parameter for the at least one associated dryer being used during the at least one of the drying stages. Herein, the at last one known value for the at least one setting parameter for the at least one associated dryer may, preferably, be acquired in at least one test drying process by using at least one known preparation on at least one known substrate which comprises at least one test layout of the at least two consecutive drying stages. The computer-implemented method according to any one of the preceding embodiments, wherein the at least one model is based on at least one of a composition of the preparation, at least one parameter related to at least one property of at least one component of the preparation, at least one measured value for at least one material parameter related to the at least one coating after the at least two drying stages, at least one known influence on crack formation in the at least one coating, and at least one value for an energy consumption as a consequence of the at least one setting parameter for the at least one associated dryer being used during at least one of the drying stages.

As a result of the test drying process, at least one relationship may be generated, wherein the at least one relationship may, preferably, refer to a plurality of values for the least one material parameter of the coating on the at least one substrate, specifically a peel strength indicating an adhesion of the at least one coating on the at least one side of the at least one substrate, and a plurality of setting parameters of an associated dryer in a corresponding drying zone. As exemplarily illustrated below, the at least one relationship may be displayed as at least one diagram, preferably a plurality of diagrams, in a two-, a three-, or a more-dimensional fashion. Herein, the at least one diagram may, especially, depict the relationship between the peel strength of the applied coating on the substrate and both the individual temperature profile and the individual heat transfer profile as applied during the corresponding drying stages to at least one particular preparation on at least one particular substrate. Herein, based on the at least one diagram which may, especially, depict the relationship between the peel strength of the applied coating on the substrate and both the individual temperature profile and the individual heat transfer profile as applied during the corresponding drying stages, the predictive value for both the individual temperature profile and the individual heat transfer profile within the particular drying stage may be determined in this fashion.

In a particularly preferred embodiment, the model may be generated by applying a combination of at least one data processing method, a set of selected features, and at least one learning algorithm. As generally used, the term “data processing method” refers to a process of modifying raw data, in particular a plurality of known values for the at least one setting parameter for the at least one associated dryer being used during the at least one of the drying stages, especially by using at least one of a correction algorithm, a smoothing algorithm, or a scaling algorithm. Further, the set of selected features may refer to at least one particular data item, preferably a plurality of values for the least one material parameter of the coating on the at least one substrate, specifically a peel strength indicating an adhesion of the at least one coating on the at least one side of the at least one substrate. As further generally used, the term “learning algorithm” relates to a process of extracting at least one pattern in at least one known set of data, wherein the at least one pattern can, thereafter, be applied to at least one unknown set of data. In addition, by using further unknown sets of data the at least one pattern can further be refined. Herein, the learning algorithm may, preferably, be selected from a machine-learning algorithm or a deep learning algorithm.

In particular, the determining of the at least one predictive value for the at least one setting for the at least one associated dryer being used during the at least one of the drying stages by using the information about the layout of the at least two consecutive drying stages, about the composition of the preparation, and about the at least one substrate may, preferably, be performed by applying the at least one learning algorithm to a combination of known predictive values with known pieces of information. Herein, the learning algorithm may involve at least one algorithm selected from at least one of a regression algorithm or a classification algorithm. By way of, example at least one of the following algorithms may be used: partial least square regression; discriminant analysis; a Bayesian algorithm such as Naïve Bayes, Brute-force MAP learning, Bayes Belief Networks, Bayes optimal classifier; Support Vector machines with multiple kernels; a decision tree algorithm such as random forest, CART; logistic and linear regression such as LASSO, Ridge, elastic net; a statistical analysis such as univariate generalized and mixed models; a neural network (NN) algorithm such as Fully connected NN, convolutional NN, recurrent NN; Gaussian modelling such as Gaussian process regression, Gaussian graphical networks; unsupervised learning methods such as non-negative matrix factorization, principal component analysis (PCA), t-sne, LLE. However, a further type of learning algorithm may also be feasible.

According to step (iii), the at least one predictive value for the at least one setting parameter for the at least one associated dryer being used during the at least one of the drying stages is determined based on the at least one model as employed during step (ii) and the information as received during step (i). For this purpose, the programmable apparatus as described elsewhere herein in more detail can, preferably, be used. Regarding step (iii) it has to be noted that this step is particularly not carried out by the user of the dryer apparatus but by a third party receiving the above-mentioned information such as a supplier of the preparation. This third party then starts the calculation procedure for determining the predictive value for the setting parameter(s). Thus, step (iii) relates to a prediction of a setting parameter which is subsequently useable for the drying process.

According to step (iv), at least one recommended procedure for adjusting the at least one drying process is provided. Herein, the at least one recommended procedure comprises the at least one predictive value for the at least one setting parameter for the at least one associated dryer being used during the at least one of the drying stages. As used herein, the term “recommended procedure” refers to a set of data comprising at least one proposal for adjusting the at least one drying process. Herein, the recommended procedure may, in particular, be provided to a user in order to initiate the user to implement at least one of, preferably all, of the proposals for adjusting the at least one drying process, for example by altering the tape speed and/or the at least one setting parameter for each associated dryer as used within the drying zones in the coating device, specifically in a manual fashion. As an alternative as described below in more detail, the recommended procedure can be provided to a control unit which is configured to control the coating device, especially by using at least one communication interface configured to exchange information between a programmable apparatus comprising a processing unit configured to generate the recommended procedure and the control unit. Regarding step (iv) it has to be noted that this step is particularly not carried out by the user of the dryer apparatus but by a third party receiving the above-mentioned information such as a supplier of the preparation. This third party then—having carried out the calculation procedure for determining the predictive value for the setting parameter—provides the user of the dryer apparatus with the recommended procedure. With other words, the third party provides a kind of manual or prescription and sends it to the user of the dryer apparatus which then may carry out the drying process according to the recommended procedure.

Briefly summarizing the first aspect of the present disclosure, the method may involve two different parties. The first party is the operator of a drying apparatus providing information about a layout of the at least two consecutive drying stages, about a composition of the preparation, and about the at least one substrate. The second party may be partly separate or remote from the first party. The second party predicts a recommended procedure for operating the drying apparatus based on the information provided by the first party and subsequently forwards the recommended procedure to the first party which then may correspondingly adjust the drying process.

In a further aspect, the present invention refers to a system for adjusting at least one drying process designated for producing at least one coating on at least one substrate. Herein, the system comprises:
at least one processing unit, wherein the at least one processing unit is configured to perform a computer-implemented method for adjusting at least one drying process designated for producing at least one coating on at least one substrate as described elsewhere herein;
at least one communication interface configured to receive the information about a layout of the at least two consecutive drying stages, about a composition of the preparation, and about the at least one substrate; and
at least one further communication interface configured to provide at least one recommended procedure for adjusting the at least one drying process which comprises the at least one predictive value for the at least one setting parameter for the at least one associated dryer being used during the at least one of the drying stages.

In a preferred embodiment, the at least one further communication interface may be configured to provide the recommended procedure to a user, in particular via the screen. However, a further device for providing the recommended procedure to the user may also be feasible, such as a loudspeaker.

In a further preferred embodiment, the at least one further communication interface may be configured to provide the recommended procedure to a control unit configured to control the coating device.

In a further aspect, the present invention refers to a use of a computer-implemented method or of a system for adjusting at least one drying process designated for producing at least one coating on at least one substrate, in particular as described elsewhere herein, in an electrode for a vehicle application. Specifically, the use may refer to a positive electrode or a negative electrode for a battery, such as a lithium ion battery, which can be used in a vehicle application. More particular, the use may refer to a method for producing an electrode, specifically a positive electrode or a negative electrode for a battery, such as a lithium ion battery, as used in a vehicle application. However, further uses of the computer-implemented method or of the system for adjusting at least one drying process designated for producing at least one coating on at least one substrate may also be feasible, such as in producing at least one photoactive layer which can be used in a coating of a solar cell, such as in a photovoltaic solar panel.

In a further aspect, the present invention refers to a system for adjusting at least one drying process designated for producing at least one coating. Herein, the system comprises:
at least one component of at least one preparation to be used in at least one drying process, wherein the at least one drying process comprises at least two consecutive drying stages after which at least one coating is produced by using the at least one component; and
at least one recommended procedure for adjusting the at least one drying process, wherein the at least one recommended procedure comprises at least one predictive value for at least one setting parameter for at least one associated dryer being used during the at least one of the drying stages.

For further details with respect to the system for adjusting the at least one drying process designated for producing the at least one coating on the at least one substrate, the use of a computer-implemented method or of a system for adjusting at least one drying process designated for producing at least one coating on at least one substrate, and the system for adjusting at least one drying process designated for producing at least one coating, reference may be made to the description of the computer-implemented method for adjusting at least one drying process designated for producing at least one coating on at least one substrate and to the system for continuously producing the at least one coating on the at least one substrate as described elsewhere herein.

In a further aspect of the present invention, a method for continuously producing at least one coating on at least one substrate disclosed. The method comprises the following steps a) to f), which may, preferably, be performed in the given order, wherein at least two of the steps may be performed in an overlapping fashion in time. In addition, the method may comprise further steps which may be elsewhere be described herein or not. Accordingly, the method for continuously producing the at least one coating on the at least one substrate comprises the following steps:
a) introducing at least one tape into a coating device, wherein the coating device is configured to move the at least one tape with a tape speed through at least one application area and at least two consecutive drying zones, wherein each drying zone comprises at least one associated dryer, wherein the coating device is further configured to adjust at least one of the tape speed and at least one setting parameter for the at least one associated dryer in each drying zone;
b) depositing at least one preparation onto at least one side of at least one substrate in the at least one application area, wherein the at least one tape is or comprises the at least one substrate, or wherein the at least one tape carries the at least one substrate;
c) employing at least one model configured to generate at least one predictive value for the tape speed and for the at least one setting parameter for at least one associated dryer in the at least one of the drying zones based on information about a layout of the at least two drying zones, about a composition of the preparation, and about the at least one substrate;
d) determining the at least one predictive value for at least one of the tape speed and the at least one setting parameter for the at least one associated dryer in the at least one of the drying zones based on the at least one model and the information;
e) adjusting the at least one drying process by using at least one recommended procedure which comprises the at least one predictive value for at least one of the tape speed and the at least one setting parameter for the at least one associated dryer in the at least one of the drying zones; and
f) drying the at least one preparation within the at least two consecutive drying zones, whereby the at least one coating is obtained.

For further details concerning the method for continuously producing at least one coating on at least one substrate, reference may be made to the description of computer-implemented method as presented herein according to one or more of the embodiments presented above or below in further detail.

In a further aspect of the present invention, a system for continuously producing at least one coating on at least one substrate is disclosed. Accordingly, the system comprises
a coating device, wherein the coating device comprises
   at last one conveyor drive configured to move at least one tape with a tape speed;
   at least one application area configured to provide at least one preparation to be deposited onto at least one side of the tape; and
   at least two consecutive drying zones configured to dry the at least one preparation, wherein each drying zone comprises at least one associated dryer;
at least one programmable apparatus, wherein the at least one programmable apparatus is configured to:
   (i) receive information about a layout of the at least two consecutive drying zones, about a composition of the preparation, about the at least one substrate, and about the tape speed;
   (ii) employ at least one model configured to generate at least one predictive value for at least one of the tape speed and at least one setting parameter for at least one associated dryer being used within at least one of the drying zones;
   (iii) determine the at least one predictive value for at least one of the tape speed and the at least one setting parameter for the at least one associated dryer within the at least one of the drying zones based on the at least one model and the information; and
   (iv) provide at least one recommended procedure for adjusting the at least one drying process which comprises the at least one predictive value for at least one of the tape speed and the at least one setting parameter for the at least one associated dryer within the at least one of the drying zones; and
at least one control unit configured to
   interact with the at least one programmable apparatus; and
   to control the coating device by adjusting the at least one drying process by implementing at least one recommended procedure.

As generally used, the term “drying zone” refers to a partition of the coating device which comprises at least one associated dryer that is operated by at least one value for at least one setting parameter as used within the drying zone. In particular, the at least one setting parameter for associated dryer may comprise at least one of an individual temperature and an individual heat transfer which may be applied within the corresponding drying zone. For this purpose, each drying zone may, preferably, comprise at least one of a heating unit or a cooling unit which can be controlled by at least one temperature control unit which configured to control the at least one individual temperature, and at least one blowing unit which designed to set the at least one individual heat transfer. By using multiple drying zones temperature and heat transfer profiles can be applied. Needless to say, a temperature and heat transfer profile can be realized in a single drying zone by varying the temperature and heat transfer, particularly over time.

As further used herein, the term “control unit” refers to an arbitrary kind of apparatus which is configured to control the coating device. In contrast to the term “adjusting” as defined above, the term “controlling” or grammatical variations thereof not only refers to for arranging at least one parameter of the drying process in an desired fashion but includes, in addition, reviewing whether the at least one parameter of the drying process has been adjusted in the desired fashion and, if required, further adjusting and reviewing the at least one parameter of the drying process. For a purpose of reviewing the at least one parameter of the drying process the coating unit may, in particular, comprise at least one sensor unit. Herein, the at least one sensor unit may, especially, be configured to record at least one measured value for at least one material parameter of the coating after the at least two consecutive drying zones. The sensor unit may, in particular, be configured to measure a temperature at at least one surface of the at least one coating, preferably by comprising at least one optical sensor, specifically at least one infrared sensor. Alternatively or in addition, the at least one sensor unit may be configured to measure a thickness or a coating weight per area of the at least one coating, preferably comprising using at least one of an ultrasonic sensor, an optical confocal sensor, an optical interference-based sensor, a laser triangulation sensor, a gamma-radiation based sensor, or a beta-radiation based sensor. Alternatively or in addition, the at least one sensor unit may be configured to measure a composition of the at least one coating, preferably by comprising a sensor based on infrared spectroscopy or on Raman spectroscopy. Alternatively or in addition, the at least one sensor unit may be configured to measure a structural information related to the at least one coating, preferably by comprising an eddy current sensor or a sensor based on optical microscopy, confocal microscopy, fluorescence microscopy, or interferometry. Alternatively or in addition, the at least one sensor unit may be configured to measure the gas phase composition such as the fraction of evaporating solvent preferably by using at least one of a flame ionization detector or other common gas sensors. However, further kinds of sensors may also be feasible.

In particular, the at least one control unit may comprise at least one further processing unit and a plurality of interface and, optionally at least one further device selected from at least one of a storage unit, a monitor, or a keyboard, Herein, the at least one further processing unit may, especially, be configured to drive the coating device, in particular by using the plurality of interfaces. Herein, at least one, preferably all, of the interfaces may be arranged as a bidirectional communication interface configured to transmit at least one piece of data into one of two directions, or vice versa. In particular, the interfaces can be used as bidirectional communication interfaces, preferably, in one direction, for transmitting instructions, especially for adjusting the at least one drying process by implementing the recommended procedure, from the at least one control unit to at least one of the at least one conveyor drive, the at least one application area, or the at least two consecutive drying zones, especially the temperature control unit and the blowing unit as comprised by each drying zone, and, in the other direction, for transmitting messages from at least one of the at least one conveyor drive, the at least one application area, or the at least two consecutive drying zones to the at least one control unit, such as data items, measurement values, or error messages. Further, the at least one control unit may be configured to interact with the at least one programmable apparatus, in particular, by using at least one, preferably bidirectional, communication interface. As an alternative, the at least one control unit and the at least one programmable apparatus may can be implemented within at least one combined programmable apparatus, especially in an embodiment in which the at least one combined programmable apparatus may be comprised by a stand-alone computer, a server, or a computer network.

For further details concerning the system for continuously producing at least one coating on at least one substrate, reference may be made to the description of computer-implemented method as presented herein according to one or more of the embodiments presented above or below in further detail.

In a further aspect of the present invention, a computer-implemented method for providing at least one recommended procedure for adjusting at least one drying process designated for producing at least one coating on at least one substrate is disclosed. Herein, the at least one drying process is applied to at least one preparation deposited on the at least one substrate, wherein the at least one drying process comprises at least two consecutive drying stages after which the at least one coating is produced. According to the present invention, the method comprises the following steps:
(i) providing information about a layout of the at least two consecutive drying stages, about a composition of the preparation, and about the at least one substrate;
(ii) employing at least one model configured to generate at least one predictive value for at least one setting parameter for at least one associated dryer being used during at least one of the drying stages;
(iii) determining the at least one predictive value for the at least one setting for the at least one associated dryer being used during the at least one of the drying stages based on the at least one model and the information; and
(iv) receiving at least one recommended procedure for adjusting the at least one drying process which comprises the at least one predictive value for the at least one setting parameter for the at least one associated dryer being used during the at least one of the drying stages.

The methods and the systems according to the present invention provide various advantages with respect to methods and systems producing at least one coating on at least one substrate as known from prior art. In particular, it allows an individual setting of drying conditions in each drying zone in order to adjust the drying conditions during each drying stage. As a result of the possible adjusting of the drying process according to the present invention, a quality of a product whose manufacturing includes the at least one drying process can be improved at constant or increasing efficiency of the drying process. Hereby, at least one of a throughput during the production, a performance of the at least one coating, and an energy consumption during the drying process can be affected in a positive manner.

Particularly, the methods and the systems according to the present disclosure provide significant advantages if compared to design of experiments (DOE). Particularly, DOE is time, material, energy and resources consuming, particularly concerning production scale. A transfer of laboratory data to production scale usually requires a pilot apparatus which in turn is rather expensive. To the contrary, the method according to the present disclosure does not involve any experimental procedures but relates to a predictive procedure. Thus, a user of a drying or coating apparatus gains more time for manufacturing procedures rather than wasting time for optimizing the process. Thereby, the method according to the present disclosure is sustainable as it requires significant less raw materials and resources and does not require a pilot apparatus. Thus, the time necessary for the development from laboratory to production scale is significantly shortened and provides more time for the development of the coating process. Particularly, small adaptions or variations of the slurry manufacturing and/or coating process may be compensated and do not require complex and enduring experiments. Thus, the adjusted drying process increases the throughput which otherwise requires a new drying profile. Thus, more time for development of battery or solar cells is provided.

As used further herein, the terms “have”, “comprise” or “include” or any arbitrary grammatical variations thereof are used in a non-exclusive way. Thus, these terms may both refer to a situation in which, besides the feature introduced by these terms, no further features are present in the entity described in this context and to a situation in which one or more further features are present. As an example, the expressions “A has B”, “A comprises B” and “A includes B” may both refer to a situation in which, besides B, no other element is present in A (i.e. a situation in which A solely and exclusively consists of B) and to a situation in which, besides B, one or more further elements are present in entity A, such as element C, elements C and D or even further elements.

Further, as used herein, the terms “preferably”, “more preferably”, “particularly”, “more particularly”, “specifically”, “more specifically” or similar terms are used in conjunction with optional features, without restricting alternative possibilities. Thus, features introduced by these terms are optional features and are not intended to restrict the scope of the claims in any way. The invention may, as the skilled person will recognize, be performed by using alternative features. Similarly, features introduced by “in an embodiment of the invention” or similar expressions are intended to be optional features, without any restriction regarding alternative embodiments of the invention, without any restriction regarding the scope of the invention and without any restriction regarding the possibility of combining the features introduced in such a way with other optional or non-optional features of the invention.

Summarizing the above-mentioned findings, the following embodiments are preferred within the present invention:
Embodiment 1: A computer-implemented method for adjusting at least one drying process designated for producing at least one coating on at least one substrate, wherein the at least one drying process is applied to at least one preparation deposited on the at least one substrate, wherein the at least one drying process comprises at least two consecutive drying stages after which the at least one coating is produced, wherein the method comprises the following steps:
   (i) receiving information about a layout of the at least two consecutive drying stages, about a composition of the preparation, and about the at least one substrate;
   (ii) employing at least one model configured to generate at least one predictive value for at least one setting parameter for at least one associated dryer being used during at least one of the drying stages;
   (iii) determining the at least one predictive value for the at least one setting parameter for the at least one associated dryer being used during the at least one of the drying stages based on the at least one model and the information; and
   (iv) providing at least one recommended procedure for adjusting the at least one drying process which comprises the at least one predictive value for the at least one setting parameter for the at least one associated dryer suitable for being used during the at least one of the drying stages.
Embodiment 2: The computer-implemented method according to the preceding embodiment, wherein the at least one model is generated by using at least one known value for the at least one setting parameter for the at least one associated dryer being used during the at least one of the drying stages.
Embodiment 3: The computer-implemented method according to the preceding embodiment, wherein the at last one known value for the at least one setting parameter for the at least one associated dryer is acquired in at least one test drying process comprising at least one test layout of the at least two consecutive drying stages.
Embodiment 4: The computer-implemented method according to any one of the preceding embodiments, wherein the at least one model is based on at least one of a composition of the preparation, at least one parameter related to at least one property of at least one component of the preparation, at least one measured value for at least one material parameter related to the at least one coating after the at least two drying stages, at least one known influence on crack formation in the at least one coating, and at least one value for an energy consumption as a consequence of the at least one setting parameter for the at least one associated dryer being used during at least one of the drying stages.
Embodiment 5: The computer-implemented method according to the preceding embodiment, wherein the at least one material parameter related to the at least one coating after the at least two drying stages is selected from at least one parameter related to at least one of an adhesion of the at least one coating on the at least one substrate and a performance of the at least one coating in at least one application.
Embodiment 6: The computer-implemented method according to any one of the two preceding embodiments, wherein the at least one model is generated by applying an optimizing procedure in which it is intended to increase at least one value of the at least one parameter related to at least one of an adhesion of the at least one coating on the at least one substrate and of the performance of the at least one coating in at least one application and to decrease at least one value for the at least one known influence on crack formation in the at least one coating and the at least one value for an energy consumption.
Embodiment 7: The computer-implemented method according to the preceding embodiment, wherein the at least one coating on the at least one substrate is designated for producing a battery electrode, wherein in the optimizing procedure it is further intended to increase an electrode performance of the at least one coating in at least one application of the at least one battery electrode in an electrochemical cell.
Embodiment 8: The computer-implemented method according to the pre-preceding embodiment, wherein the at least one coating on the at least one substrate is designated for producing a photoactive layer in a solar cell, wherein in the optimizing procedure it is further intended to increase an electrical performance of the at least one coating in at least one application of the at least one solar cell in a photovoltaic solar panel.
Embodiment 9: The computer-implemented method according to any one of the five preceding embodiments, wherein the at least one measured value for the at least one material parameter is related to at least one of a temperature at a surface of the at least one coating, a thickness or a coating weight per area of the at least one coating, a composition of the at least one coating, or a structural information related to the at least one coating.
Embodiment 10: The computer-implemented method according to the preceding embodiment, wherein the at least one measured value for the temperature at the surface of the at least one coating is recorded by using at least one optical sensor.
Embodiment 11: The computer-implemented method according to any one of the two preceding embodiments, wherein the at least one measured value for the thickness or the coating weight per area of the at least one coating is recorded by using at least one of an ultrasonic sensor, an optical confocal sensor, an optical interference-based sensor, a laser triangulation sensor, a gamma-radiation based sensor, or a beta-radiation based sensor.
Embodiment 12: The computer-implemented method according to any one of the three preceding embodiments, wherein the at least one measured value for the composition of the at least one coating is recorded by using a sensor based on infrared spectroscopy or on Raman spectroscopy.
Embodiment 13: The computer-implemented method according to any one of the four preceding embodiments, wherein the at least one measured value for the structural information related to the at least one coating is recorded by using an eddy current sensor or a sensor based on optical microscopy, confocal microscopy, fluorescence microscopy, or interferometry.
Embodiment 14: The computer-implemented method according to any one of the preceding embodiments, wherein the consecutive drying stages comprise at least one initial drying stage and at least one critical drying stage following the at least one initial drying stage.
Embodiment 15: The computer-implemented method according to the preceding embodiment, wherein the at least one setting parameter for the at least one associated dryer is adjusted during the at least one critical drying stage to differ from the at least one setting parameter for the at least one associated dryer as adjusted during the at least one initial drying stage.
Embodiment 16: The computer-implemented method according to any one of the two preceding embodiments, comprising at least three consecutive drying stages, wherein the at least three consecutive drying stages further comprise at least one final drying stage following the at least one critical drying stage.
Embodiment 17: The computer-implemented method according to the preceding embodiment, wherein the at least one setting parameter for the at least one associated dryer during the at least one final drying stage is adjusted to differ from the at least one setting parameter for the at least one associated dryer as adjusted during the at least one critical stage.
Embodiment 18: The computer-implemented method according to any one of the preceding embodiments, wherein the at least one recommended procedure comprises adjusting the at least one setting parameter for the at least one associated dryer to a constant value during the at least one drying stage.
Embodiment 19: The computer-implemented method according to any one of the preceding embodiments, wherein the at least one setting parameter for the at least one associated dryer comprises at least one of an individual temperature profile and an individual heat transfer profile during the at least one drying stage.
Embodiment 20: The computer-implemented method according to the preceding embodiment, wherein the adjusting of the at least one individual temperature profile is performed by setting at least one temperature control unit.
Embodiment 21: The computer-implemented method according to any one of the two preceding embodiments, wherein the adjusting of the at least one individual heat transfer profile is performed by setting at least one blowing unit.
Embodiment 22: The computer-implemented method according to any one of the preceding embodiments, wherein the producing of the at least one coating on the at least one substrate is performed in a continuous manner by continuously depositing the at least one preparation onto the at least one substrate.
Embodiment 23: The computer-implemented method according to the preceding embodiment, wherein at least one tape is or comprises the at least one substrate, or wherein the at least one tape carries the at least one substrate, wherein the at least one tape is moved during the at least two consecutive drying stages with a tape speed.
Embodiment 24: The computer-implemented method according to the preceding embodiment, wherein the at least one model is further configured to generate a predictive value for the tape speed, wherein the predictive value for the tape speed is further determined, and wherein the at least one recommended procedure for adjusting the at least one drying process further comprises outputting the predictive value for the tape speed.
Embodiment 25: A system for adjusting at least one drying process designated for producing at least one coating on at least one substrate, the system comprising:
   at least one processing unit, wherein the at least one processing unit is configured to perform a computer-implemented method for adjusting at least one drying process designated for producing at least one coating on at least one substrate according to any one of the preceding embodiments;
   at least one communication interface configured to receive the information about a layout of the at least two consecutive drying stages, about a composition of the preparation, and about the at least one substrate; and
   at least one further communication interface configured to provide the at least one recommended procedure for adjusting the at least one drying process which comprises the at least one predictive value for the at least one setting parameter for the at least one associated dryer being used during the at least one of the drying stages.
Embodiment 26: The system according to the preceding embodiment, comprising at least one bidirectional communication interface, wherein the at least one bidirectional communication interface comprises the at least one communication interface and the at least one further communication interface.
Embodiment 27: The system according to any one of the preceding system embodiments, wherein the at least one further communication interface is configured to provide the recommended procedure to a user.
Embodiment 28: The system according to the preceding embodiment, further comprising a screen, wherein the at least one further communication interface is configured to provide the recommended procedure to a user via the screen.
Embodiment 29: The system according to any one of the preceding system embodiments, wherein the at least one further communication interface is configured to provide the recommended procedure to a control unit configured to control the coating device.
Embodiment 30: A use of a computer-implemented method or of a system for adjusting at least one drying process designated for producing at least one coating on at least one substrate according to any one of the preceding embodiments an electrode for a vehicle application.
Embodiment 31: A system for adjusting at least one drying process designated for producing at least one coating, the system comprising:
   at least one component of at least one preparation to be used in at least one drying process, wherein the at least one drying process comprises at least two consecutive drying stages after which at least one coating is produced by using the at least one component; and
   at least one recommended procedure for adjusting the at least one drying process, wherein the at least one recommended procedure comprises at least one predictive value for at least one setting parameter for at least one associated dryer being used during the at least one of the drying stages.
Embodiment 32: A method for continuously producing at least one coating on at least one substrate, the method comprising the following steps:
   a) introducing at least one tape into a coating device, wherein the coating device is configured to move the at least one tape with a tape speed through at least one application area and at least two consecutive drying zones, wherein each drying zone comprises at least one associated dryer, wherein the coating device is further configured to adjust at least one of the tape speed and at least one setting parameter for the at least one associated dryer in each drying zone;
   b) depositing at least one preparation onto at least one side of at least one substrate in the at least one application area, wherein the at least one tape is or comprises the at least one substrate, or wherein the at least one tape carries the at least one substrate;
   c) employing at least one model configured to generate at least one predictive value for the tape speed and for the at least one setting parameter for at least one associated dryer in the at least one of the drying zones based on information about a layout of the at least two drying zones, about a composition of the preparation, and about the at least one substrate;
   d) determining the at least one predictive value for at least one of the tape speed and the at least one setting parameter for the at least one associated dryer in the at least one of the drying zones based on the at least one model and the information;
   e) adjusting the at least one drying process by using at least one recommended procedure which comprises the at least one predictive value for at least one of the tape speed and the at least one setting parameter for the at least one associated dryer in the at least one of the drying zones; and
   f) drying the at least one preparation within the at least two consecutive drying zones, whereby the at least one coating is obtained.
Embodiment 33: The method according to the preceding embodiment, wherein the at least one setting parameter for the at least one associated dryer comprises at least one of an individual temperature profile and an individual heat transfer profile within the at least one drying zone.
Embodiment 34: The computer-implemented method according to the preceding embodiment, wherein the adjusting of the at least one individual temperature profile is performed by setting at least one temperature control unit.
Embodiment 35: The computer-implemented method according to any one of the two preceding embodiments, wherein the adjusting of the at least one individual heat transfer profile is performed by setting at least one blowing unit.
Embodiment 36: The method according to the preceding embodiment, wherein at least one drying stage is performed within the one drying zone.
Embodiment 37: The method according to the preceding embodiment, wherein a particular drying stage is performed within a particular drying zone.
Embodiment 38: The method according to any one of the five preceding embodiments, wherein at least one of the individual temperature profile and the individual heat transfer profile in the at least one drying zone is adjusted to a constant value over an extension of the at least one drying zone along a movement of the tape.
Embodiment 39: The method according to any one of the preceding seven embodiments, wherein the at least one preparation comprises a plurality of particles, at least one binder and at least one solvent, wherein the at least one coating is formed by a combination of particle consolidation, binder migration and solvent evaporation over the at least two consecutive drying zones.
Embodiment 40: The method according to the preceding embodiment, wherein the consecutive drying zones comprise at least one initial drying zone and at least one critical drying zone following the at least one initial drying zone.
Embodiment 41: The method according to the preceding embodiment, wherein at least one of an initial temperature profile and an initial heat transfer profile are adjusted in the at least one initial drying zone to support a shrinkage of the at least one preparation prior to forming a pore network by the plurality of the coating particles.
Embodiment 42: The method according to any one of the two preceding embodiments, wherein at least one of a critical temperature profile and a critical heat transfer profile are adjusted in the at least one critical drying zone to support the forming of the pore network by the plurality of the coating particles and to initiate the solvent evaporation from the pore network.
Embodiment 43: The method according to any one of the four preceding embodiments, comprising at least three consecutive drying zones, wherein the three consecutive drying zones further comprise at least one final drying zone following the at least one critical drying zone,
Embodiment 44: The method according to the preceding embodiment, wherein at least one of a final temperature profile and a final heat transfer profile are adjusted in the at least one final drying zone to support the solvent evaporation from the pore network.
Embodiment 45: A system for continuously producing at least one coating on at least one substrate, the system comprising:
   a coating device, wherein the coating device comprises
      at last one conveyor drive configured to move at least one tape with a tape speed;
      at least one application area configured to provide at least one preparation to be deposited onto at least one side of the tape; and
      at least two consecutive drying zones configured to dry the at least one preparation, wherein each drying zone comprises at least one associated dryer;
   at least one programmable apparatus, wherein the at least one programmable apparatus is configured to:
      (i) receive information about a layout of the at least two consecutive drying zones, about a composition of the preparation, about the at least one substrate, and about the tape speed;
      (ii) employ at least one model configured to generate at least one predictive value for at least one of the tape speed and at least one setting parameter for at least one associated dryer being used within at least one of the drying zones;
      (iii) determine the at least one predictive value for at least one of the tape speed and the at least one setting parameter for the at least one associated dryer within the at least one of the drying zones based on the at least one model and the information; and
      (iv) provide at least one recommended procedure for adjusting the at least one drying process which comprises the at least one predictive value for at least one of the tape speed and the at least one setting parameter for the at least one associated dryer within the at least one of the drying zones; and
   at least one control unit configured to
      interact with the at least one programmable apparatus; and
      to control the coating device by adjusting the at least one drying process by implementing at least one recommended procedure.
Embodiment 46: The system according to the preceding embodiment, wherein each drying zone is configured to perform at least one drying stage.
Embodiment 47: The system according to the preceding embodiment, wherein a particular drying zone is configured to perform a particular drying stage.
Embodiment 48: The system according to any one of the preceding system embodiments, wherein the coating device further comprises at least one sensor.
Embodiment 49: The system according to the preceding embodiment, wherein at least one sensor is selected from at least one sensor configured to measure a temperature at a surface of the at least one coating, at least one sensor configured to measure a thickness or a coating weight per area of the at least one coating, at least one sensor configured to measure a composition of the at least one coating, or at least one sensor configured to measure a structural information related to the at least one coating.
Embodiment 50: The system according to the preceding embodiment, wherein at least one optical sensor is used for recording at least one measured value for the temperature at the surface of the at least one coating.
Embodiment 51: The system according to any one of the two preceding embodiments, wherein at least one of an ultrasonic sensor, an optical confocal sensor, an optical interference-based sensor, a laser triangulation sensor, a gamma-radiation based sensor, or a beta-radiation based sensor is used for recording the at least one measured value for the thickness or the coating weight per area of the at least one coating.
Embodiment 52: The system according to any one of the three preceding embodiments, wherein a sensor based on infrared spectroscopy or on Raman spectroscopy is used for recording the at least one measured value for the composition of the at least one coating.
Embodiment 53: The system according to any one of the four preceding embodiments, wherein an eddy current sensor or a sensor based on optical microscopy, confocal microscopy, fluorescence microscopy, or interferometry is used for recording the at least one measured value for the structural information related to the at least one coating.
Embodiment 54: The system according to any one of the preceding system embodiments, wherein the at least one programmable apparatus is or is comprised by at least one mobile communication device.
Embodiment 55: The system according to any one of the preceding system embodiments, wherein the at least one mobile communication device comprises at least one of a smartphone, a tablet, or a personal digital assistant.
Embodiment 56: The system according to any one of the preceding system embodiments, wherein the at least one programmable apparatus communicates with the control unit via at least one communication interface.
Embodiment 57: A computer-implemented method for providing at least one recommended procedure for adjusting at least one drying process designated for producing at least one coating on at least one substrate is disclosed, wherein the at least one drying process is applied to at least one preparation deposited on the at least one substrate, wherein the at least one drying process comprises at least two consecutive drying stages after which the at least one coating is produced wherein the method comprises the following steps:
   (i) providing information about a layout of the at least two consecutive drying stages, about a composition of the preparation, and about the at least one substrate;
   (ii) employing at least one model configured to generate at least one predictive value for at least one setting parameter for at least one associated dryer being used during at least one of the drying stages;
   (iii) determining the at least one predictive value for the at least one setting for the at least one associated dryer being used during the at least one of the drying stages based on the at least one model and the information; and
   (iv) receiving at least one recommended procedure for adjusting the at least one drying process which comprises the at least one predictive value for the at least one setting parameter for the at least one associated dryer being used during the at least one of the drying stages.
Embodiment 58: A kit comprising:
   a material for a coating of an electrode, particularly a battery electrode, and at least one recommended procedure for adjusting at least one drying process which comprises the at least one predictive value for the at least one setting parameter for the at least one associated dryer being used during the at least one of the drying stages determined according to embodiment 1.

### BRIEF DESCRIPTION OF THE FIGURES

Further optional details and features of the invention are evident from the description of preferred exemplary embodiments which follows in conjunction with the dependent Embodiments. In this context, the particular features may be implemented alone or in any reasonable combination. The invention is not restricted to the exemplary embodiments. The exemplary embodiments are shown schematically in the figures. Identical reference numerals in the individual figures refer to identical elements or elements with identical function, or elements which correspond to one another with regard to their functions.

In the Figures:

FIG. 1 illustrates a preferred embodiment of a system for producing a coating on both sides of a tape;

FIG. 2 illustrates drying profiles of differently designed drying processes over time;

FIGS. 3A to 3D illustrate experimental results obtained by adjusting the at least one drying process according to the present invention;

FIG. 4 illustrates a preferred embodiment of a computer-implemented method for adjusting at least one drying process designated for producing at least one coating on at least one substrate; and

FIG. 5 illustrates a preferred embodiment of a system for adjusting at least one drying process designated for producing at least one coating on at least one substrate.

### EXEMPLARY EMBODIMENTS

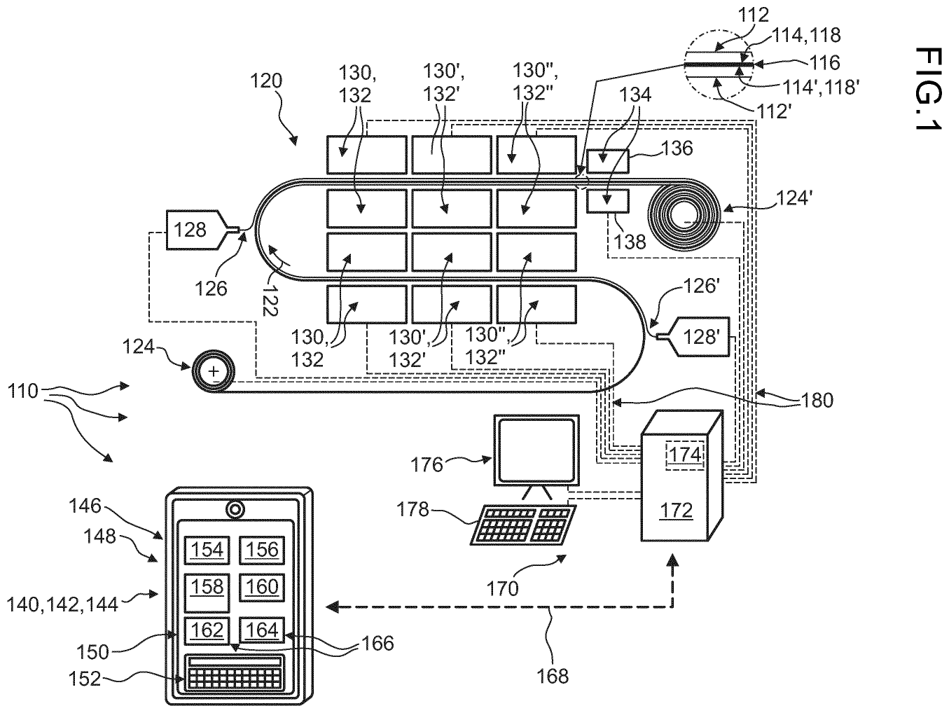

FIG. 1 schematically illustrates a preferred embodiment of a system 110 for producing a coating 112, 112′ on one or both sides 114, 114′ of a tape 116, wherein each side 114, 114′ of the tape 116 may function as a substrate 118,118′ for the respective coating 112, 112′. As an alternative, a separate substrate (not depicted here) can be carried by one or both sides 114, 114′ of the tape 116, wherein the coating 112, 112′ may be applied to separate substrate, respectively.

The system 110 according to the present invention comprises a coating device 120. Herein, the coating device 120 has a conveyor drive which is configured to move the tape 116 with a tape speed 122. As schematically depicted in FIG. 1, the conveyor drive comprises a first drum 124 which carries and provides the uncoated tape 116 and a second drum 124′ which receives the coated tape 116. In general, it is sufficient that the first drum 124 may be powered to move the tape 116 forward with the desired tape speed 122 while the second drum 124′ may functions as an unpowered idle drum. However, further kinds of arrangements of the conveyor drive may also be conceivable.

Further, the coating device 120 as schematically illustrated in FIG. 1 has two individual application areas 126, 126′, wherein each application area 126, 126′ comprises an individual coating unit 128, 128′ which is configured to provide a preparation that is deposited onto each side 114, 114′ of the tape 116 which functions as the respective substrate 118,118′. However, a different number or arrangement of the applications areas 126, 126′ may also be feasible. By way of example, a single application area 126 for producing only a single coating 112 on a single side 114 of the tape 116 may also be possible. As a further example, at least two applications areas 126, 126′ may be used for consecutively depositing at least two individual coatings 112, 112′ on the same side 114 of the tape 116. In general, the preparation as well as the number and the particular arrangement of the application areas 126, 126′ depend on the envisaged application of the coating 112, 112′. By way of example, the preparation may be used for producing a coating 112, 112′ on one or both sides 114, 114′ of the tape 116 which is designated for being used in a battery electrode. As a further example, the preparation may be used for producing a coating 112, 112′ on one or both sides 114, 114′ of the tape 116 which is be designated for being used in a photoactive layer in a solar cell. However, further examples are conceivable. The two individual application areas 126, 126′ as comprised by the coating device 120 depicted in FIG. 1 are arranged in a fashion that the second application area 126′ deposits the preparation on the second side 114′ of the tape 116 after the coating 112 on the first side 114 of the tape 116, which has been produced by depositing the preparation on the first side 114 of the tape 116, has already been dried in a first drying process.

Further, the coating device 120 as schematically illustrated in FIG. 1 has three consecutive drying zones 130, 130′, 130″ after each individual application area 126, 126′. However, for sake of simplicity only the three consecutive drying zones 130, 130′, 130″ after the first application area 126 are described below in more detail, wherein the details are mutatis mutandis applicable to the three consecutive drying zones 130, 130′, 130″ after the second application area 126 # as also depicted in FIG. 1. Each drying zone 130, 130′, 130″ after the first application area 126 is configured to dry the preparation which has been deposited in the first application area 126 by using the first coating unit 128. For this purpose, each drying zone 130, 130′, 130″ comprises an associated dryer 132, 132′, 132″, wherein at least one setting parameter for each associated dryer 132, 132′, 132″ can be set in order to adjust the drying process. In particular, the at least one setting parameter for each associated dryer 132, 132′, 132″ may comprise at least one of an individual temperature profile and an individual heat transfer profile which may be applied within the corresponding drying zone 130, 130′, 130″.

For this purpose, each drying zone 130, 130′, 130″ may comprise at least one temperature control unit (not depicted here) which is configured to set an individual temperature profile in the corresponding drying zone 130, 130′, 130″, specifically by controlling at least one of a heating unit or a cooling unit (not depicted here). As defined above, the individual temperature profile relates to a course of the temperature prevailing at the preparation within the corresponding drying zone 130, 130′, 130″, wherein the temperature may, specifically, refer to a temperature at an accessible surface of the at least one preparation as applied on the substrate 118, 118′.

In addition, each drying zone 130, 130′, 130″ may, further comprise at least one blowing unit (not depicted here) which is configured to adjust an individual heat transfer profile in the corresponding drying zone 130, 130′, 130″. As defined above, the individual heat transfer profile refers to a course of the heat transfer applied to the preparation within the corresponding drying zone 130, 130′, 130″, wherein the heat transfer may, especially, refer to a transfer of heat above the accessible surface of the at least one preparation.

In this manner, each drying zone 130, 130′, 130″ can, preferably, be addressed individually, preferably in a fashion that at least one value for the setting parameter for the associated dryer 132′ located in a particular drying zone 130′ differs from at least one value for the setting parameter for the associated dryers 132, 132″ located in adjacent drying zones 130, 130″. This advantage allows an individual setting of drying conditions in each drying zone 130, 130′, 130″ as described above and below in more detail.

As further schematically illustrated in FIG. 1, the coating device 120 may, in addition, have a sensor unit 134 which comprises at least one sensor being configured to record at least one measured value for at least one material parameter of the coating 112, 112′ after the three consecutive drying zones 130, 130′, 130″. Herein, the at least one material parameter of the coating 112, 112′ on the substrate 118, 118′ may be used for improving the at least one drying process at constant or, preferably, increasing efficiency of the drying process. In particular, the sensor unit 134 may comprise an optical sensor 136, specifically an infrared sensor, which is configured to measure a temperature at a surface of the coating 112, 112′. Alternatively or in addition, the sensor unit 134 may comprise an ultrasonic sensor 138 which is configured to measure a coating weight per area of the coating 112, 112′. However, further kinds of sensors, such as the sensors as mentioned above, may also be feasible.

In general, the at least one material parameter of the coating 112, 112′ may depend on the nature and application of the coating 112, 112′. By way of example, the coating 112, 112′ on one or both sides 114, 114′ of the tape 116 can be a coating which is designated for being used in a battery electrode. Herein, the at least one material parameter can, preferably, be selected from a peel strength of the coating 112, 112′ on the substrate and an electrode performance of the coating 112, 112′ in an application of the battery electrode in an electrochemical cell. As a further example, the coating 112, 112′ on one or both sides 114, 114′ of the tape 116 can be designated for being used in a solar cell, wherein the at least one material parameter can be selected here from a peel strength of the coating 112, 112′ on the substrate and an electrical performance of the coating 112, 112′ in an application of the solar cell in a photovoltaic solar panel. However, further examples are feasible.

According to the present invention, the system 110 for producing the coating 112, 112′ on one or both sides 114, 114′ of the tape 116 further comprises a programmable apparatus 140. As schematically depicted in FIG. 1, the programmable apparatus 140 can be or comprise a mobile communication device 142, specifically a smartphone 144. However, a further kind of programmable apparatus, such as a computer or a computer network, or a different kind of mobile communication device, can also be used for the purposes of the present invention. However, to facilitate reading of the following passage, the particular embodiment of FIG. 1 is explained on the example of the smartphone 144, wherein the details as explained are mutatis mutandis applicable to a further kind of programmable apparatus, specifically, a computer or a computer network, or a different kind of mobile communication device.

As schematically illustrated in FIG. 1, the smartphone 144 comprises a processing unit 146 which is configured to drive the smartphone 144, in particular by running one or more applications (“apps”), wherein at least one application may be configured to determine at least one output value based on at least one input value. As further depicted here, the smartphone 144 comprises a storage unit 148 which is configured to store at least one computer program, in particular at least one computer program which drives the model that is configured to generate a simulation of the drying process as explained above and below in more detail and at least one value, in particular at least one of the output value, the input value, or a value as used in the at least one computer program. As further illustrated in FIG. 1, the smartphone 144 comprises a screen 150, wherein the screen 150 comprises a virtual keypad 152 which may be configured to receive at least one input value, especially for being processed in the processing unit 146 and/or for being stored in the storage unit 148. However, as described below in more detail, the at least one input value can, alternatively or in addition, be received via at least one different channel.

In accordance with the present invention, the smartphone 144 is configured to receive information about a layout of the at least two consecutive drying stages 130, 130′, 130″, about a composition of the preparation, about the substrate 118, 118′, and about the tape speed 122. However, at least one further piece of information may, additionally, be received by the smartphone 144. As schematically illustrated in FIG. 1, information 154 about the composition of the preparation, information 156 about the substrate 118, 118′, information 158 about the layout of the at least two consecutive drying stages 130, 130′, 130″, and information 160 about the tape speed 122 can be displayed on the screen 150, specifically, to inform a user about the information 154, 156, 158, 160, to allow the user to review the information 154, 156, 158, 160 and, if applicable, to correct the information 154, 156, 158, 160, in particular, by using the virtual keypad 152.

In further accordance with the present invention, the smartphone 144 is further configured to employ at least one model which is configured to generate a predictive value 162 for the tape speed 122 and a predictive value 164 for the at least one setting parameter for each associated dryer 132, 132′, 132″ as used within the drying zones 130, 130′, 130″.

In further accordance with the present invention, the smartphone 144 is further configured to determine the predictive values 162, 164 for the tape speed 122 and for the at least one setting parameter for each associated dryer 132, 132′, 132″ as used within the drying zones 130, 130′, 130″, respectively, based on the at least one model as employed above and the information 154, 156, 158, 160 as further received above.

In further accordance with the present invention, the smartphone 144 is further configured to provide a recommended procedure 166 for adjusting the drying process. In the embodiment as schematically depicted in FIG. 1, the recommended procedure 166 comprises the predictive values 162, 164 for the tape speed 122 and for the at least one setting parameter for each associated dryer 132, 132′, 132″ as used within the drying zones 130, 130′, 130″, respectively. As already indicated above, the storage unit 148 of the smartphone 144 is further configured to store the at least one computer program which drives the model that is configured to generate a simulation of the drying process. As defined above, the model is configured to generate the predictive values 162, 164 by using the at least one computer program that is configured to generate a simulation of the drying process, wherein the drying process comprises the three consecutive drying stages 130, 130′, 130″ as used in the coating device 120 of FIG. 1. Specifically, the simulation is closely be based on the information 154 about the composition of the preparation, the information 156 about the substrate 118, 118′, the information 158 about the layout of the at least two consecutive drying stages 130, 130′, 130″, and the information 160 about the tape speed 122 as received by the smartphone 144 as described above.

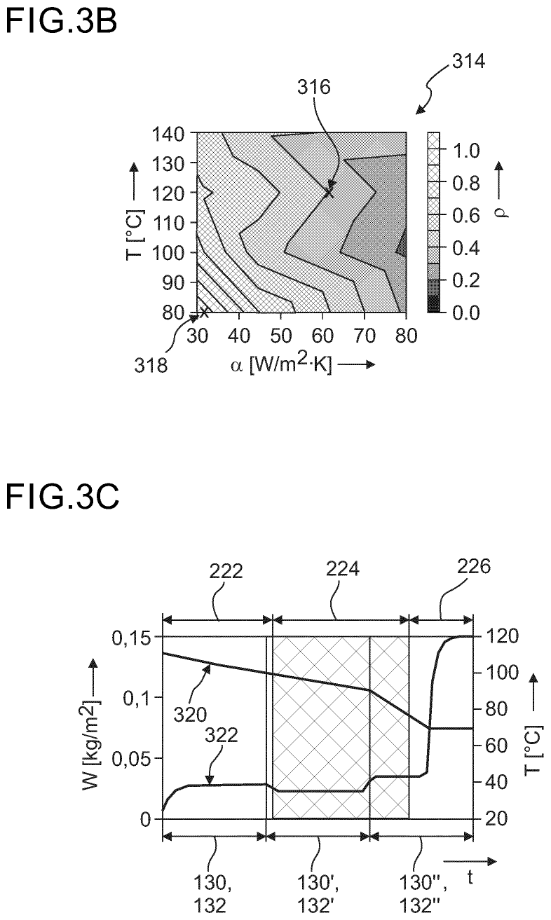

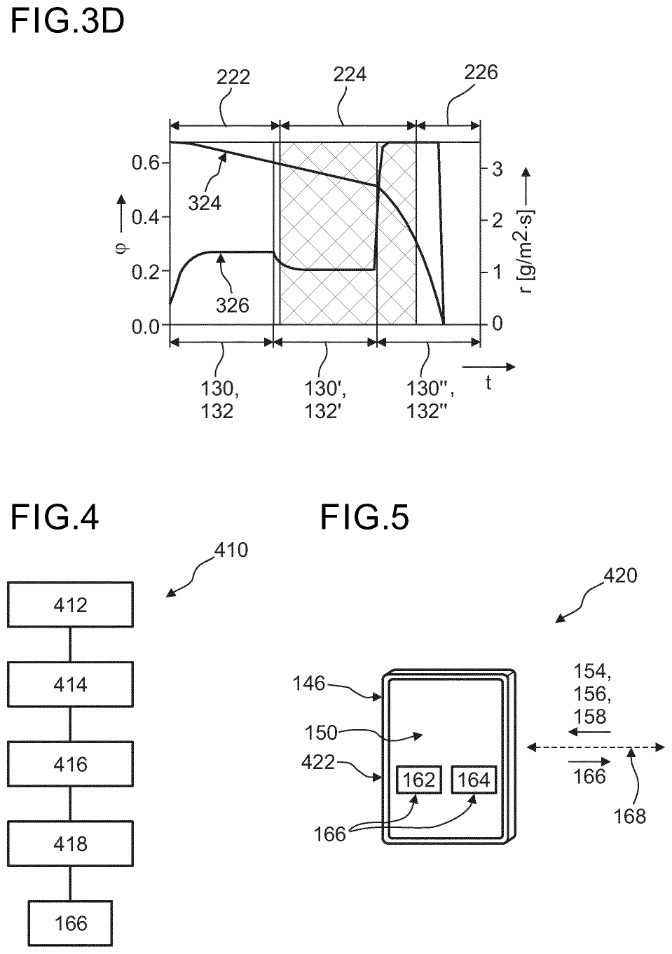

In particular, the model may be generated by using known values for the composition of the preparation, the substrate 118, 118′, the layout of the consecutive drying stages 130, 130′, 130″, the tape speed 122, the at least one setting parameter for each associated dryer 132, 132′, 132″ and for at least one material parameter of the coating 112, 112′ on the substrate 118, 118′, specifically a peel strength indicating an adhesion of the coating 112, 112′ on the substrate 118, 118′. Herein, the known values may, preferably, be acquired in at least one test drying process by using at least one known preparation on at least one known substrate which comprises at least one test layout in a test coating device and one test tape speed. As a result of the test drying process, at least one relationship may be generated, wherein the at least one relationship may, for a particular preparation on a particular substrate to be dried in a particular layout as comprised by a particular coating device, refer to a plurality of values for the at least one material parameter of the coating 112, 112′ on the substrate 118, 118′, specifically the peel strength which indicates the adhesion of the coating 112, 112′ on the substrate 118, 118′, for a plurality of setting parameters of the associated dryer 132, 132′, 132″ within the corresponding drying zones 130, 130′, 130″ and the tape speed 122. As illustrated below in FIG. 3B, the at least one relationship may be displayed as at least one diagram, wherein the at least one diagram may, especially, depict the relationship between the peel strength and both the individual temperature profile and the individual heat transfer profile as applied within during the corresponding the corresponding drying zones 130, 130′, 130″ to the particular preparation on the particular substrate.

In further accordance with the present invention, the recommended procedure 166 as provided by the smartphone 144 can initiate the user to alter the tape speed 122 and/or the at least one setting parameter for each associated dryer 132, 132′, 132″ as used within the drying zones 130, 130′, 130″ in the coating device 120, specifically in a manual fashion. However, as further shown in FIG. 1, the system 110 may, in addition, comprise at least one communication interface 168 which may, especially, be configured to exchange information between the smartphone 144 and a control unit 170 as further comprised by the system 110. Herein, the at least one communication interface 168 may comprise a wire-bound element or a wireless element. By way of example, the wire-bound element may be selected from at least one of a metal wire, such as a copper wire or a gold wire; a computer bus system, such as a universal serial bus (USB); or an optical fiber, whereas the wireless element may comprise a wireless transmitter or a Bluetooth element. However, further kinds of communication interfaces may also be feasible. Preferably, the communication interface 168 may be arranged as a bidirectional communication interface configured to transmit, in one direction, the information 154, 156, 158, 160 from the control unit 170 to the smartphone 144 and to transmit, in the other direction, the recommended procedure 166 to the control unit 170.

As schematically depicted in FIG. 1, the control unit 170 may comprise at least one further processing unit 172, a storage unit 174, a monitor 176, a keyboard 178, and a plurality of interfaces 180. Herein, the at least one further processing unit 172 may be configured to drive the coating device 120, especially by using the plurality of interfaces 180. Herein, one or more, preferably all, of the interfaces 180 may be arranged as a bidirectional communication interface which is configured to forward at least one piece of data into one of two directions, or vice versa. In particular, the interfaces 180 can be used as bidirectional communication interfaces, preferably, in one direction, for transmitting instructions from the control unit 170 to at least one of the drums 124, 124′, the coating units 128, 128′, dryers 132, 132′, 132″, or the sensor unit 134, and, in the other direction, for transmitting messages from at least one of the drums 124, 124′, the coating units 128, 128′, dryers 132, 132′, 132″, or the sensor unit 134 to the control unit 170, such as data items, measurement values, or error messages. Further, the storage unit 174 may, in particular, be configured to store any one of these data items, measurement values, or error messages which can, especially, be displayed by the monitor 176, while the keyboard 178 may, specifically, be designated for inputting at least one of these instructions and/or for correcting any one of these data items, measurement values, or error messages. In particular, the control unit 170 may be configured to interact with the smartphone 144, preferably via the communication interface 168, and, further, to control the coating device 120, preferably via the plurality of interfaces 180, by adjusting the at least one drying process by implementing the recommended procedure 166.

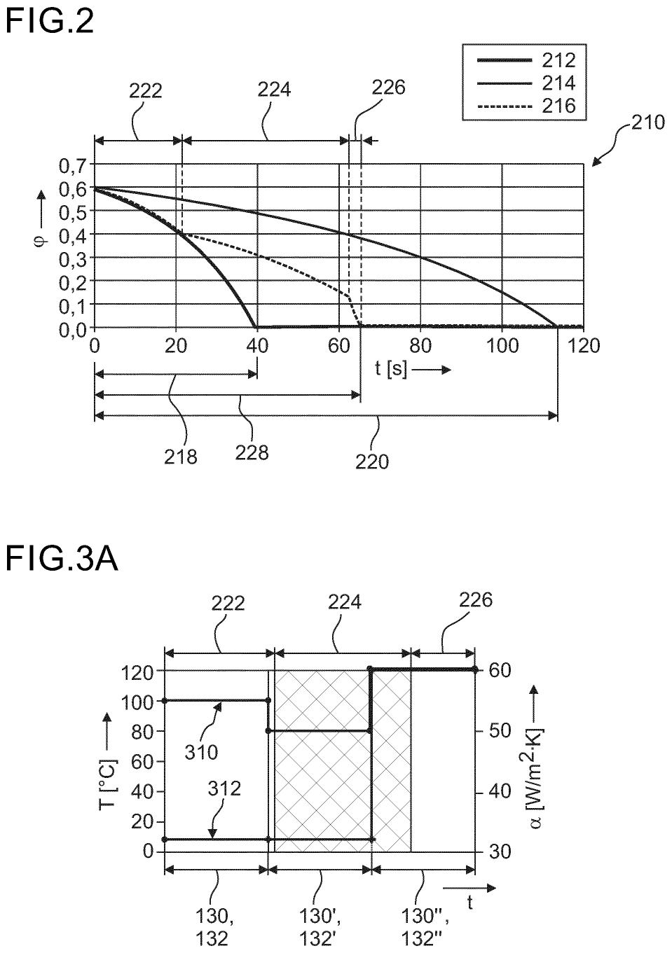

FIG. 2 shows a diagram 210, which illustrates drying profiles 212, 214, 216 of differently designed drying processes. For this purpose, a solvent volume fraction φ is plotted over time tin φ for the different drying profiles 212, 214, 216. Accordingly, the drying profile 212 which may also be denoted by the term “rough drying profile” illustrates a particular embodiment of the drying profile in which a considerably high evaporation rate (here r=3 g/m²s) may be applied to the preparation. Although the drying profile 212 may be interesting from an economic point of view, in particular, due to a reduced drying time 218, it, generally, does not provide a desired quality of the coating 112, 112′, which can be derived from records of measured values for at least one material parameter of the coating 112, 112′ after completion of the drying process.

Therefore, in order to increase the quality of the coating 112, 112′, the drying profile 214 also denoted by the term “mild dying profile” can be used in which a low high evaporation rate (here r=1 g/m²s) may be applied to the preparation, and which provides the desired values for the at least one material parameter of the coating 112, 112′ after completion of the drying process, however, on cost of a particularly increased drying time 220. For both drying profiles 212, 214 a constant value for the setting parameters for the associated dryers 132, 132′, 132″ is being used during all drying zones 130, 130′, 130″ involved.

In accordance with the present invention, the recommended procedure 166 is provided, as described above, to adjust drying process by setting the tape speed 122 and/or the at least one setting parameter for each associated dryer 132, 132′, 132″ used within the drying zones 130, 130′, 130″ as comprised by the coating device 120. As illustrated in FIG. 2, the drying process can be partitioned into three consecutive drying stages 222, 224, 226. In this preferred exemplary embodiment, the drying process can, thus, be partitioned into an initial drying stage 222, a critical drying stage 224 following the initial drying stage 222, and a final drying stage 226 which follows the critical drying stage 224. Further, one or more of the drying stages 222, 224, 226 may be partitioned onto more than one of the drying zones 130, 130′, 130″.

As can be derived from FIG. 2, the evaporation rate of drying profile 216 also denoted by the term “partitioned drying profile” follows the evaporation rate of the rough drying profile 212 during the initial drying stage 222, applies the evaporation rate of the mild drying profile 214 during the critical drying stage 224, and returns to the evaporation rate of the rough drying profile 212 during the final drying stage 226. Herein, the drying profiles 212, 214, 216 during the corresponding drying stages 222, 224, 226 can be obtained by a setting the tape speed 122 and the at least one respective setting parameter for each associated dryer 132, 132′, 132″ in each drying zone 130, 130′, 130″ of the coating device 120. Preferably, the initial drying stage 222 may be performed herein in the first drying zone 130, the critical drying stage 224 in the successive drying zone 130′, and the final drying stage 226 in the final drying zone 130″.

As a result, the drying process according to the partitioned drying profile 216 can be performed in an intermediate drying time 228 which, certainly, exceeds the drying time 218 as required for the rough drying profile 212 but which is still below the drying time 220 as required for the mild drying profile 214, by approximately 40% in this preferred exemplary embodiment, wherein a quality of the coating 112, 112′ as obtained by applying the partitioned drying profile 216 equals the quality of the coating 112, 112′ as obtained by applying the mild dying profile 214, which can be demonstrated by recording measured values for at least one material parameter of the coating 112, 112′ after completion of the drying process according to the partitioned drying profile 216.

Not wishing to be bound by theory, the results as presented in the diagram 210 of FIG. 2 can be explained by taking into account that the preparation which is applied to the substrate 118, 118′ at the beginning of the drying process comprises at least two different components, i.e. a matrix having a plurality of at least one solid component, wherein the at least one solid component may comprise a plurality of at least one of crystalline particles, amorphous particles or dissolved molecules, and a solvent having at least one second component, wherein the at least one solvent may be selected from at least one of a liquid, a gas, or a mixture thereof. In addition, the preparation may, further, comprise at least one additional component, in particular at least one binder designated to maintain the solid components within the matrix together. In order to form the coating 112, 112′ during the drying process, a combination of particle consolidation, binder migration and solvent evaporation occurs over the three consecutive drying stages 222, 224, 226. In general, immediately after having applied the preparation onto the substrate 118, 118′, the drying process, typically, starts with the initial drying stage 222 which comprises a shrinkage of a volume of the preparation on the substrate 118, 118′, mainly due to a combination of particle consolidation and solvent evaporation from the matrix. As illustrated in FIG. 2, a value for the solvent volume fraction is reduced from φ≈0.6 to φ≈0.4 during the initial drying stage 222. Thereafter, the critical stage 224, typically, begins when the shrinkage of the volume of the preparation on the substrate 118, 118′ ends and the solvent evaporation from pores between the consolidated particles starts. As experimentally demonstrated, it may, thus, be preferred to apply the mild drying profile 216 during the critical drying stage 224 (This is why the term “critical” is used for this drying stage.) to adequately support procedures which take place during the critical drying phase 224 in order to obtain a high quality of the coating 112, 112′ within as little time as possible. As further illustrated in FIG. 2, the value for the solvent volume fraction is reduced from φ≈0.4 to φ≈0.15 during the critical drying stage 224. During the final drying stage 226, the value for the solvent volume fraction is, eventually, reduced to φ≈0, wherein the considerably high evaporation rate of the rough drying profile 212 can be used, especially in order to reduce the drying time 228 as far as possible.

FIGS. 3A to 3D illustrate experimental results which have been obtained by adjusting the at least one drying process according to the present invention.

FIG. 3A displays a course 310 of the temperature T_{D} in ° C. and a course 312 of the heat transfer coefficient α in W/m²·K as the setting parameters being used for each associated dryer 132, 132′, 132″ in each drying zone 130, 130′, 130″ in order to implement the drying stages 222, 224, 226 for a particular drying process.

FIG. 3B displays a diagram 314 which illustrates experimental results for normalized a 90° peel strength p (see standard ASTM D6862 for a description of the analytical method) of the coating 112, 112′ as a function of the individual temperature profile Tin ° C. and the individual heat transfer profile α in W/m²·K as applied during the critical drying stage 224 measured for a coating weight per area w≈78.5 g/m². Herein, a first point 316 in the diagram 314 indicates an example for suboptimal conditions T≈120° C. and α≈60 W/m²·K as used for the drying procedure whereas a second point 318 in the diagram 314 indicates a further example for optimal conditions T≈80° C. and α≈30 W/m²·K used for the drying procedure according to the present invention as illustrated in FIG. 3A. The diagram 314 can be considered as results which constitute a model for the particular drying process as presented in FIG. 3A.

FIG. 3C displays a course 320 of the coating weight per area w in kg/m² of the preparation and a course 322 of the temperature T_{F} in ° C. at a surface of the preparation in each drying zone 130, 130′, 130″ implementing the drying stages 222, 224, 226. Herein, the measured values of the course 322 of the temperature T_{F} at the surface of the preparation have been recorded by using an optical sensor while the measured values of the course 320 of the coating weight per area w of the preparation have been recorded by using the ultrasonic sensor.

FIG. 3D displays a course 324 of the solvent volume fraction φ and a course 326 of an evaporation rate r in g/m²·s in each drying zone 130, 130′, 130″ implementing the drying stages 222, 224, 226. As illustrated there, the evaporation rate is particularly reduced in the drying zone 130′ which largely corresponds to the critical stage 224.

FIG. 4 schematically illustrates a preferred embodiment of a computer-implemented method 410 for adjusting the drying process designated for producing the coating 112, 112′ on the substrate 118, 118′. As already described above, the drying process is applied to the preparation deposited on the substrate 118, 118′, wherein the drying process comprises the three consecutive drying stages 222, 224, 226 after which the coating 112, 112′ is produced. According to the present invention, the method 410 comprises the following steps.

In a receiving step 412 according to step (i), the information 154, 156, 158 about the layout of the at least two consecutive drying stages 222, 224, 226, about the composition of the preparation, and about the at least one substrate 118, 118′ is received.

In a employing step 414 according to step (ii), the at least one model is employed, wherein the at least one model is configured to generate the predictive values 162, 164 for the at least one setting parameter for each associated dryer 132, 132′, 132″ as being used during the drying stages 222, 224, 226.

In a determining step 416 according to step (iii), the predictive values 162, 164 for the at least one setting parameter for each associated dryer 132, 132′, 132″ as being during the three drying stages 222, 224, 226 is determined based on the at least one model as employed in the employing step 414 and the information 154, 156, 158 as received in the receiving step 412.

In a providing step 418 according to step (iv), the recommended procedure 166 for adjusting the drying process is provided, wherein the recommended procedure 166 comprises the predictive values 162, 164 for the at least one setting parameter for each associated dryer 132, 132′, 132″ during the three drying stages 222, 224, 226.

FIG. 5 schematically illustrates a preferred embodiment of a system 420 for adjusting the drying process designated for producing the coating 112, 112′ on the substrate 118, 118′. As depicted in FIG. 5, the system 420 comprises the processing unit 146 which is configured to perform the computer-implemented method 410 for adjusting the drying process designated for producing the coating 112, 112′ on the substrate 118, 118′ as already described above.

Further, the system 420 comprises the bidirectional communication interface 168 which is configured to function, on one hand, as a first communication interface configured to receive the information 154, 156, 158 about the layout of the at least two consecutive drying stages 222, 224, 226, about the composition of the preparation, and about the at least one substrate 118, 118′, and, on the other hand, as a further communication interface configured to provide the recommended procedure 166 for adjusting the drying process, which comprises the predictive values 162, 164 for the at least one setting parameter for each associated dryer 132, 132′, 132″ during the three drying stages 222, 224, 226, to the further processing unit 172 as comprised by the control unit 170 configured to control the coating device 120.

As further illustrated In FIG. 5, the system 420 may, in addition, comprises at least one additional communication interface 422 which may be configured to provide the recommended procedure 116, in particular, including the predictive values 162, 164, to a user, especially, via the screen 150. Alternatively or in addition, the recommended procedure 166 can be provided to the user via a different device, such as a loudspeaker (not depicted here).

### LIST OF REFERENCE NUMBERS

110 system for continuously producing at least one coating on at least one substrate
112, 112′ coating
114, 114′ side
116 tape
118, 118′ substrate
120 coating device
122 tape speed
124, 124′ drum
126, 126′ application area
128, 128′ coating unit
130, 130′, 130″ drying zone
132, 132′, 132″ associated dryer
134 sensor unit
136 optical sensor
138 ultrasonic sensor
140 programmable apparatus
142 mobile communication device
144 smartphone
146 processing unit
148 storage unit
150 screen
152 virtual keypad
154 information
156 information
158 information
160 information
162 predictive value
164 predictive value
166 recommended procedure
168 (bidirectional) communication interface
170 control unit
172 further processing unit
174 storage unit
176 monitor
178 keyboard
180 interface
210 diagram
212 rough drying profile
214 mild drying profile
216 partitioned drying profile
218 drying time
220 drying time
222 initial drying stage
224 critical drying stage
226 final drying stage
228 drying time
310 course of individual temperature
312 course of individual heat transfer coefficient
314 diagram
316 suboptimal point
318 optimal point
320 course of coating weight per area
322 course of surface temperature
324 course of solvent volume fraction
326 course of evaporation rate
410 computer-implemented method for adjusting at least one drying process designated for producing at least one coating on at least one substrate
412 receiving step
414 employing step
416 determining step
418 providing step
420 system for adjusting at least one drying process designated for producing at least one coating on at least one substrate
422 additional communication interface

1. A computer-implemented method for adjusting at least one drying process designated for producing at least one coating on at least one substrate, wherein the at least one drying process is applied to at least one preparation deposited on the at least one substrate, wherein the at least one drying process comprises at least two consecutive drying stages after which the at least one coating is produced, wherein the method comprises:
(i) receiving information about a layout of the at least two consecutive drying stages, about a composition of the preparation, and about the at least one substrate;
(ii) employing at least one model configured to generate at least one predictive value for at least one setting parameter for at least one associated dryer being used during at least one of the drying stages;
(iii) determining the at least one predictive value for the at least one setting parameter for the at least one associated dryer being used during the at least one of the drying stages based on the at least one model and the information; and
(iv) providing at least one recommended procedure for adjusting the at least one drying process which comprises the at least one predictive value for the at least one setting parameter for the at least one associated dryer suitable for being used during the at least one of the drying stages.

2. The computer-implemented method according to claim 1, wherein the at least one model is generated by using at least one known value for the at least one setting parameter for the at least one associated dryer being used during the at least one of the drying stages, wherein the at least one known value for the at least one setting parameter for the at least one associated dryer is acquired in at least one test drying process comprising at least one test layout of the at least two consecutive drying stages.

3. The computer-implemented method according to claim 1, wherein the at least one model is based on at least one of a composition of the preparation, at least one parameter related to at least one property of at least one component of the preparation, at least one measured value for at least one material parameter related to the at least one coating after the at least two drying stages, at least one known influence on crack formation in the at least one coating, and at least one value for an energy consumption as a consequence of the at least one setting parameter for the at least one associated dryer being used during at least one of the drying stages.

4. The computer-implemented method according to claim 3, wherein the at least one material parameter related to the at least one coating after the at least two drying stages is selected from at least one parameter related to at least one of an adhesion of the at least one coating on the at least one substrate and a performance of the at least one coating in at least one application.

5. The computer-implemented method according to claim 3, wherein the at least one model is generated by applying an optimizing procedure in which it is intended to increase at least one value of the at least one parameter related to at least one of an adhesion of the at least one coating on the at least one substrate and of the performance of the at least one coating in at least one application and to decrease at least one value for the at least one known influence on crack formation in the at least one coating and the at least one value for an energy consumption.

6. The computer-implemented method according to claim 1, wherein the consecutive drying stages comprise at least one initial drying stage and at least one critical drying stage following the at least one initial drying stage, wherein the at least one setting parameter for the at least one associated dryer is adjusted during the at least one critical drying stage to differ from the at least one setting parameter for the at least one associated dryer as adjusted during the at least one initial drying stage.

7. The computer-implemented method according to claim 6, further comprising at least three consecutive drying stages, wherein the at least three consecutive drying stages further comprise at least one final drying stage following the at least one critical drying stage, wherein the at least one setting parameter for the at least one associated dryer during the at least one final drying stage is adjusted to differ from the at least one setting parameter for the at least one associated dryer as adjusted during the at least one critical stage.

8. The computer-implemented method according to claim 1, wherein the at least one recommended procedure comprises adjusting the at least one setting parameter for the at least one associated dryer to a constant value during the at least one drying stage.

9. The computer-implemented method according to claim 1, wherein the at least one setting parameter for the at least one associated dryer comprises at least one of an individual temperature profile and an individual heat transfer profile during the at least one drying stage.

10. The computer-implemented method according to claim 9, wherein the at least one recommended procedure comprises adjusting at least one of the individual temperature profile by setting at least one temperature control unit and the individual heat transfer profile by setting at least one blowing unit.

11. The computer implemented method according to claim 1, further comprising providing the information about a layout of the at least two consecutive drying stages, about a composition of the preparation, and about the at least one substrate and receiving the at least one recommended procedure for adjusting the at least one drying process which comprises the at least one predictive value for the at least one setting parameter for the at least one associated dryer suitable for being used during the at least one of the drying stages.

12. The computer-implemented method according to claim 1, wherein the producing of the at least one coating on the at least one substrate is performed in a continuous manner by continuously depositing the at least one preparation onto the at least one substrate, wherein at least one tape is or comprises the at least one substrate, or wherein the at least one tape carries the at least one substrate, wherein the at least one tape is moved during the at least two consecutive drying stages with a tape speed, wherein the at least one model is further configured to generate a predictive value for the tape speed, wherein the predictive value for the tape speed is further determined, and wherein the at least one recommended procedure for adjusting the at least one drying process further comprises outputting the predictive value for the tape speed.

13. A system for adjusting at least one drying process designated for producing at least one coating on at least one substrate, the system comprising:
at least one processing unit, wherein the at least one processing unit is configured to perform a computer-implemented method for adjusting at least one drying process designated for producing at least one coating on at least one substrate, wherein the at least one drying process is applied to at least one preparation deposited on the at least one substrate, wherein the at least one drying process comprises at least two consecutive drying stages after which the at least one coating is produced, wherein the method comprises:
(i) receiving information about a layout of the at least two consecutive drying stages, about a composition of the preparation, and about the at least one substrate;
(ii) employing at least one model configured to generate at least one predictive value for at least one setting parameter for at least one associated dryer being used during at least one of the drying stages;
(iii) determining the at least one predictive value for the at least one setting parameter for the at least one associated dryer being used during the at least one of the drying stages based on the at least one model and the information; and
(iv) providing at least one recommended procedure for adjusting the at least one drying process which comprises the at least one predictive value for the at least one setting parameter for the at least one associated dryer being used during the at least one of the drying stages;
at least one communication interface configured to receive the information according to step (i); and
at least one further communication interface configured to provide the at least one recommended procedure for adjusting the at least one drying process according to step (iv).

14. A system for adjusting at least one drying process designated for producing at least one coating, the system comprising:
at least one component of at least one preparation to be used in at least one drying process, wherein the at least one drying process comprises at least two consecutive drying stages after which at least one coating is produced by using the at least one component; and
at least one recommended procedure for adjusting the at least one drying process, wherein the at least one recommended procedure comprises at least one predictive value for at least one setting parameter for at least one associated dryer being used during the at least one of the drying stages.

15. A method for continuously producing at least one coating on at least one substrate, the method comprising:
a) introducing at least one tape into a coating device, wherein the coating device is configured to move the at least one tape with a tape speed through at least one application area and at least two consecutive drying zones, wherein each drying zone; comprises at least one associated dryer, wherein the coating device is further configured to adjust at least one of the tape speed and at least one setting parameter for the at least one associated dryer in each drying zone;
b) depositing at least one preparation onto at least one side of at least one substrate in the at least one application area, wherein the at least one tape is or comprises the at least one substrate, or wherein the at least one tape carries the at least one substrate;
c) employing at least one model configured to generate at least one predictive value for the tape speed and for the at least one setting parameter for at least one associated dryer in the at least one of the drying zones based on information about a layout of the at least two drying zones, about a composition of the preparation, and about the at least one substrate;
d) determining the at least one predictive value for at least one of the tape speed and the at least one setting parameter for the at least one associated dryer in the at least one of the drying zones based on the at least one model and the information;
e) adjusting the at least one drying process by using at least one recommended procedure which comprises the at least one predictive value for at least one of the tape speed and the at least one setting parameter for the at least one associated dryer in the at least one of the drying zones; and
f) drying the at least one preparation within the at least two consecutive drying zones, whereby the at last one coating is obtained.

16. A system for continuously producing at least one coating on at least one substrate, the system comprising:
a coating device, wherein the coating device comprises
at last one conveyor drive configured to move at least one tape with a tape speed;
at least one application area configured to provide at least one preparation to be deposited onto at least one side of the tape; and
at least two consecutive drying zones configured to dry the at least one preparation, wherein each drying zone comprises at least one associated dryer;
at least one programmable apparatus, wherein the at least one programmable apparatus is configured to:
(i) receive information about a layout of the at least two consecutive drying zones, about a composition of the preparation, about the at least one substrate, and about the tape speed;
(ii) employ at least one model configured to generate at least one predictive value for at least one of the tape speed and at least one setting parameter for at least one associated dryer being used within at least one of the drying zones;
(iii) determine the at least one predictive value for at least one of the tape speed and the at least one setting parameter for the at least one associated dryer within the at least one of the drying zones based on the at least one model and the information; and
(iv) provide at least one recommended procedure for adjusting the at least one drying process which comprises the at least one predictive value for at least one of the tape speed and the at least one setting parameter for the at least one associated dryer within the at least one of the drying zones; and
at least one control unit configured to
interact with the at least one programmable apparatus; and
to control the coating device by adjusting the at least one drying process by implementing at least one recommended procedure.
